(19) United States
(12) Patent Application Publication
(10) Pub. No.: US 2025/0007515 A1
(43) Pub. Date: Jan. 2, 2025

(54) ADAPTING TO SUPPLY VOLTAGE STRESS AT A SYSTEM BASIS CHIP

(71) Applicant: Microchip Technology Incorporated, Chandler, AZ (US)

(72) Inventors: Lars Beilschmidt, Karlsruhe (DE); Venkatraman lyer, Austin, TX (US); Hongming An, San Diego, CA (US); Shivanand I. Akkihal, Austin, TX (US)

(21) Appl. No.: 18/759,523

(22) Filed: Jun. 28, 2024

Related U.S. Application Data
(60) Provisional application No. 63/511,121, filed on Jun. 29, 2023.

(51) Int. Cl. H03K 19/003; H03K 19/00; H03K 19/0175

(52) U.S. Cl. CPC H03K 19/003; H03K 19/0016; H03K 19/017509

(57) ABSTRACT

An apparatus may include a voltage source, a voltage protection circuit, and a chip powered at least in part via the voltage protection circuit. The chip may include at least one regulated voltage source; and a logic circuit. The logic circuit may determine a state of a supply voltage produced by the voltage protection circuit; determine a state of an input voltage produced by the voltage source; and determine and indicate a predicted state of the supply voltage produced by the voltage protection circuit or a predicted state of the at least one regulated voltage source, in either case at least partially based on the determined state of the supply voltage produced by the voltage protection circuit and the determined state of the input voltage produced by the voltage source.

### CROSS-REFERENCE TO RELATED APPLICATION

This application claims the benefit under 35 U.S.C. § 119(e) of U.S. Provisional Patent Application Ser. No. 63/511,121, filed Jun. 29, 2023, the contents and disclosure of which is hereby incorporated herein in its entirety by this reference.

### FIELD

Examples relate, generally, to voltage protection and a system basis chip that adapts to voltage supply stress.

### BACKGROUND

Integrated circuits (ICs) are utilized in a variety of operational contexts and may be subject to a variety of stresses.

### BRIEF DESCRIPTION OF THE DRAWINGS

To easily identify the discussion of any particular element or act, the most significant digit or digits in a reference number refer to the figure number in which that element is first introduced.

FIG. 1 is a diagram of a system in accordance with one or more examples.

FIG. 2 is a diagram of a system in accordance with one or more examples.

FIG. 3 is a block diagram of a system in accordance with one or more examples.

FIG. 4 is an example of a selective voltage protection circuit that includes an input for receiving control signals from the SBC.

FIG. 5, FIG. 6, and FIG. 7 are examples of conditions that may result in battery stresses. Turning to FIG. 5, it depicts a table at the top and a graph at the bottom.

FIG. 8 illustrates an example process for determining a predicted state of a supply voltage that powers a chip or a regulated voltage source of the chip, in accordance with one or more examples.

FIG. 9 illustrates an example process for generating a control signal to trigger a voltage protection mechanism based on a predicted state of a supply voltage powering a chip or a regulated voltage source of the chip, in accordance with one or more examples.

FIG. 10 illustrates an example process for determining a supply voltage condition, in accordance with one or more examples.

FIG. 11 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

As used herein, the terms “assert,” “de-assert” and derivatives thereof used in reference to a pin, means, respectively, to assert or de-assert a signal associated with the pin (e.g., a signal specifically assigned to the pin or a signal to which the pin is specifically assigned, without limitation).

A system basis chip (SBC) is an integrated circuit (IC) that combines multiple functions for operation of an electronic system. An SBC typically integrates various, different functions into a single chip, including, as non-limiting examples: power management functions such as voltage regulators, power switches, or protection circuitry, without limitation, to manage the power supply for the system; communication interfaces such as CAN (Controller Area Network), LIN (Local Interconnect Network), SPI (Serial Peripheral Interface), or I2C (Inter-Integrated Circuit), without limitation; embedded systems such as state machines or microprocessors, without limitation, that control and coordinate tasks; analog functions such as analog-to-digital converters (ADCs), digital-to-analog converters (DACs), temperature sensors, and other signal conditioning circuitry; and diagnostic and safety functions, such as monitoring and reporting voltage levels, temperature, or fault conditions, without limitation.

SBCs are found in a variety of operational contexts, including automotive and industrial applications. A non-limiting example of an automotive application for SBC is in 10SPE (i.e., 10 Mbps Single Pair Ethernet) networks (also called “10BASE-T1S networks”). 10SPE is a network technology specified in IEEE 802.3 clause 147 and 148. 10SPE may be used to provide a collision-free, deterministic transmission on a multi-drop network.

In some cases, a transceiver and controller of a 10SPE physical layer device (PHY) may be located on different die, as a non-limiting example, so the die undergo different processing conditions. This is referred to herein as a “split-PHY” architecture. The digital blocks of a PHY controller, which are susceptible to damage during high voltage temperature processes may be located on a first die that does not undergo high voltage temperature processes. Analog and digital blocks of a PHY transceiver, which are not susceptible to damage during high voltage temperature processes or require such processes may be located on a second die that does undergo such high voltage temperature processes.

The 10SPE Transceiver Interface standard currently under specification development by Technology Committee 14 of the OPEN Alliance (hereinafter the “TC14 Standard”) defines a 3-pin hardware interface for communication between a PHY transceiver and PHY controller.

The 10SPE controller functions are implemented at a microcontroller (MCU) and the 10SPE transceiver functions are implemented at an SBC. In addition to 10SPE transceiver functions, the SBC can implement non-transceiver functions, i.e., functions of the electronic system, such as power management, watchdog circuit, monitors, general purpose input/output (GPIO), without limitation.

In 10SPE, the SBC's responsibilities include communication transceiver, low-voltage power, observability/control of high voltage domain and functional safety mechanisms for MCU to reach safe state.

In some applications, a battery is the main power source for an electronic system. As a non-limiting example, some or a totality of automotive electronics draw power from a battery (e.g., an automobile battery, boat battery, plane battery, without limitation). Such a battery is typically high voltage (e.g., about 12 volts (V), without limitation) compared to the MCU (and in some cases, even compared to the automotive electronics), which typically operates on a low voltage (e.g., about 3.3V, without limitation).

The SBC provides infrastructure for a low voltage communications network. The SBC draws power from the battery and delivers regulated and quiet 3.3V power using a low dropout regulator (LDO). The battery voltage may swing dramatically during stress events like load dump or cold crank. The SBC may experience over temperature when battery voltage spikes (e.g., during load dump, without limitation) or a brownout or power-on reset (POR) when battery voltage craters (e.g., during cold crank, without limitation). In such circumstances, the SBC may not be able to provide a reliable regulated supply voltage to the MCU.

A voltage protection circuit is sometimes used to protect the SBC and, indirectly, the MCU, but it may not be able to react before voltage stresses are seen at the voltage supply input of the SBC.

One or more examples relate, generally, to an SBC that monitors the battery voltage and informs the MCU of stress events. The MCU can enter or exit, as the case may be, lower power or safe states based on the information received from the SBC. The SBC may control an external voltage protection circuit to mitigate voltage stresses seen at the SBC.

One or more examples relate, generally, to a System Basis Chip that collects information about one or more predicted states of an input voltage, a supply voltage, or both. The detectable states may be associated with states of an on-chip voltage source or stresses on the system, such as voltage spikes, brownouts, Power-On-Resets (POR), without limitation. Information about predicated states may be utilized to take actions that mitigate against stresses associated with the predicted states. As a non-limiting example, managing a voltage protection circuit to mitigate stresses associated with a predicted state of the battery voltage or supply voltage. In various examples, a predicted state refers to a potential future condition of the battery voltage or supply voltage.

As a non-limiting example, the SBC measures battery voltage, supply voltage (the main power source for the electronic system), or both and informs the MCU of excursions above/below pre-set thresholds. The MCU then has the option to take actions to mitigate the impact of the excursions. For example, additionally or alternatively to triggering a voltage protection mechanism, the microcontroller may transition to a low power state that reduces load on the supply voltage at least partially responsive to the determined supply voltage condition.

As a non-limiting example, the battery supply provides power (e.g., supply voltage) to the SBC and MCU via a voltage protection circuit. The SBC monitors the supply voltage and manages the voltage protection circuit in response to excursions above or below predetermined thresholds.

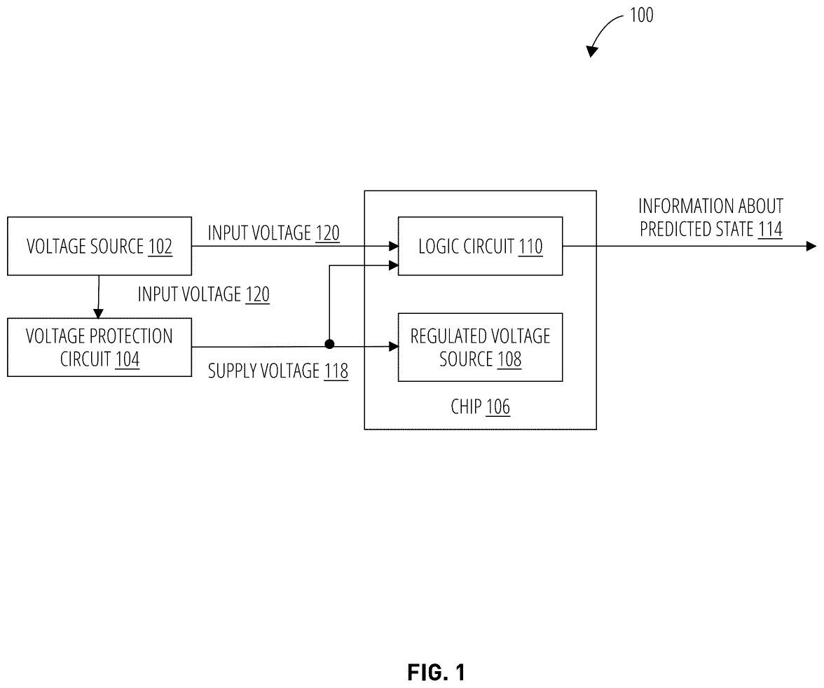

FIG. 1 is a diagram of a system 100 in accordance with one or more examples. System 100 includes a voltage source 102, a voltage protection circuit 104, a chip 106, a regulated voltage source 108, and a logic circuit 110.

Voltage source 102 may be any suitable source of voltage for a System Basis Chip, the specific type may depend on specific operating conditions. For example, voltage source 102 may be a supply, a battery, or a bus, without limitation. Voltage source 102 provides input voltage 120 to voltage protection circuit 104, which utilizes input voltage 120 to produce supply voltage 118. Supply voltage 118 is provided to regulated voltage source 108 and is used by regulated voltage source 108 to supply power to chip 106.

Logic circuit 110 receives supply voltage 118 and input voltage 120, information about supply voltage 118 or input voltage 120, or values derived, directly or indirectly (e.g., via processing) of supply voltage 118 or input voltage 120 and determines a predicted state of the supply voltage 118 and/or regulated voltage source 108. Logic circuit 110 provides information about predicted state 114, which may be used, as a non-limiting example, by a microcontroller unit (MCU) or another device as discussed, below. In one or more examples, logic circuit 110 determine a state of an output of the voltage protection circuit, determine a state of an output of the voltage source; and determine and indicates a predicted state of the supply voltage or the at least one regulated voltage source at least partially based on the output of the first logic circuit and the output of the second logic circuit, as discussed below.

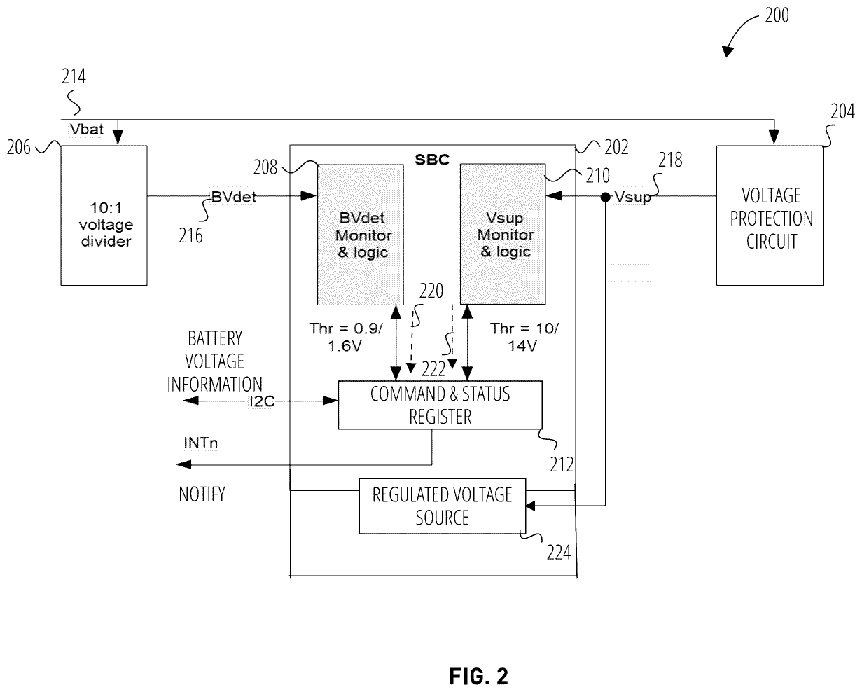

FIG. 2 is a diagram of a system 200 in accordance with one or more examples. System 200 includes a system basis chip 202 (“SBC 202”), a voltage protection circuit 204, and an optional voltage divider 206. The SBC 202 includes a battery voltage monitor and logic 208 (“BVdet monitor & logic 208”), a voltage supply monitor and logic 210 (Vsup monitor & logic 210), a command and status register 212 (“CSR 212”), and a regulated voltage source 224.

The BVdet monitor & logic 208 monitors, directly or indirectly (e.g., via battery voltage detection signal 216 (“BVdet”) produced by voltage divider 206, without limitation), the battery voltage 214 (denoted “Vbat”), compares battery voltage 214 to various predetermined thresholds (“Thr,” in this example 0.9 volts and 1.6 volts), determines a state of the battery voltage 214 at least partially based on such comparisons, and outputs an indication 220 of the state of the battery voltage 214.

In one or more examples, Vsup monitor & logic 210 monitors the voltage received at the supply input of the SBC (i.e., monitors the supply voltage 218) as supply voltage 218 (denoted “Vsup”), which is utilized by regulated voltage source 224 to supply power to SBC 202. The supply voltage 218 is provided by the voltage protection circuit 204 and is based on battery voltage 214. Vsup monitor & logic 210 compares supply voltage 218 to various predetermined thresholds (“Thr,” in this example 10 volts and 14 volts), determines a state of the supply voltage 218 at least partially based on the comparison, and outputs an indication 222 of the state of the supply voltage 218.

CSR 212 is a logic circuit (e.g., logic and registers, without limitation) that receives commands for devices or components, including without limitation BVdet monitor & logic 208 and Vsup monitor & logic 210 and receives, determines, and reports status information of aspects of SBC 202 or system 200 more generally, including without limitation battery voltage 214 and supply voltage 218 (e.g., receives, determines, and reports information about states of battery voltage 214 and supply voltage 218, without limitation). CSR 212 may also be referred to herein as a “logic circuit 212.”

CSR 212 receives and decodes the respective output of BVdet monitor & logic 208 and Vsup monitor & logic 210. Table 1 (below) describes states of the battery voltage 214 that may be determined and indicated by BVdet monitor & logic 208: an under voltage trip state, and an over voltage trip state. Table 2 (also below) describes states of the supply voltage 218 that may be determined and indicated by Vsup monitor & logic 210. Determination and indication of other states by BVdet monitor & logic 208 or Vsup monitor & logic 210 does not exceed the scope of this disclosure and is optional.

TABLE 1
Threshold values in Table 1 may be stored at BVdet monitor
& logic 208, CSR 212, or both. In some examples, the values
of the thresholds are programmable at CSR 212, which provides
the thresholds to BVdet monitor & logic 208.

| Indications of the State of | |
|---|---|
| the Battery Voltage | Thresholds Utilized to Determine State |
| UV trip set voltage | V_{TH1} |
| UV trip clear voltage | V_{TH2} |
| OV trip set voltage | V_{TH3} |
| OV trip clear voltage | V_{TH4} |

TABLE 2
Threshold values in Table 2 may be stored at Vsup monitor
& logic 210, CSR 212, or both. In some examples, the values
of these thresholds are programmable at CSR 212, which
provides the thresholds to Vsup monitor & logic 210.

| Indication of the State of the Supply | Thresholds Utilized to Determine |
|---|---|
| Voltage | State |
| OV trip set voltage | V_{TH5} |
| OV trip clear voltage | V_{TH6} |

In one or more examples, CSR 212 sends the information output by BVdet monitor & logic 208 and Vsup monitor & logic 210, such as indication of state of battery voltage 220 or indication of state of supply voltage 222, or status information determined based thereon, as discussed below, to a microcontroller unit (MCU, MCU not depicted) or notifies the MCU that status information, including the information about a predicted state of battery voltage 214 is available to read. The MCU can use that information, for example, to mitigate potential harm (adaptation).

In one or more examples, CSR 212 determines a predicted state of the battery voltage based on the outputs of BVdet monitor & logic 208 and Vsup monitor & logic 210. CSR 212 may inform an MCU of a predicted state determined by CSR 212, or determine other information based on one or more predicted states and provide other information to the MCU. In some examples, CSR 212 may optionally include logic to determine stresses associated with predicted states or mitigations to stresses associated with predicted states at least partially based on one or more predicted states respectively of battery voltage 214 or supply voltage 218. Additionally or alternatively, an MCU may include the logic to determine stresses associated with predicted states or mitigations to stresses associated with predicted states at least partially based on one or more predicted states respectively of battery voltage 214 or supply voltage 218. Additionally or alternatively to triggering a voltage protection mechanism, the MCU may transition to a low power state that reduces load on the supply voltage at least partially responsive to the determined supply voltage condition.

The SBC 202 or MCU may take one or more actions based on the information provided by the CSR 212, such as learn more information about the predicted states, or mitigate the potential harm (adaptation) via management of voltage protection circuit 204.

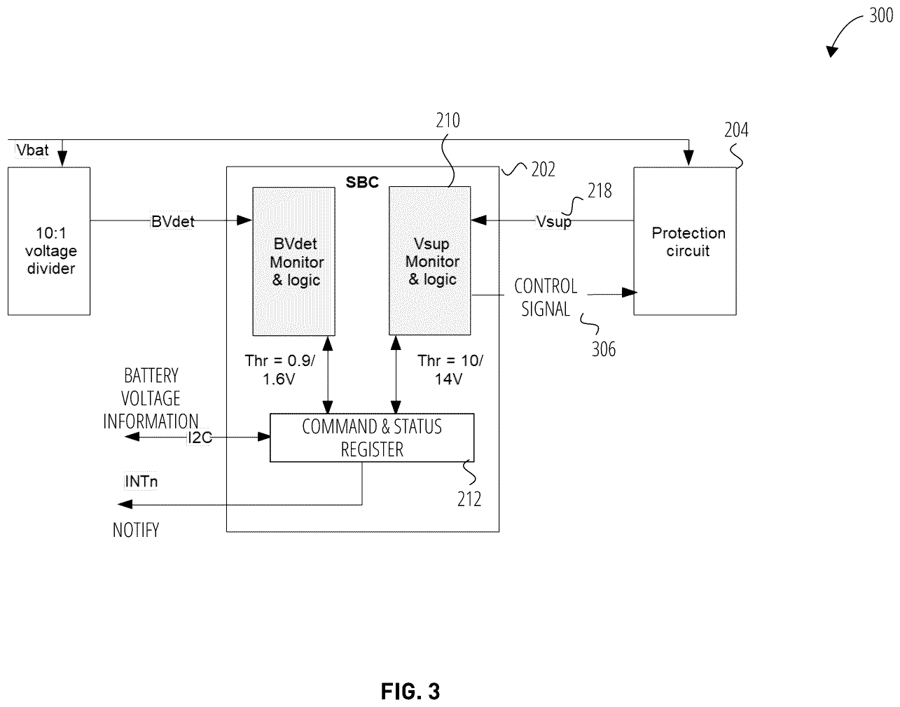

FIG. 3 is a block diagram of a system 300 in accordance with one or more examples. The SBC 202, Vsup monitor & logic 210, or CSR 212 via Vsup monitor & logic 210 communicates (e.g., directly or via a bus or other connection) with the voltage protection circuit 204 and more specifically provides control signal 306 to activate (e.g., trigger, without limitation) a protective mechanism at the voltage protection circuit 204 when predetermined conditions are met. In one or more examples, a protection mechanism may regulate the timing, level, or both of supply voltage 218 to mitigate potential stresses, such as reducing or preventing them before they occur, without limitation.

Additionally or alternatively, in one or more examples an MCU may send control signal to the voltage protection circuit 204 via the SBC 202. In such examples, the MCU includes logic for determining and generating control signals, which it can communicate to voltage protection circuit 204 or to SBC 202 for the voltage protection circuit 204, e.g., via a bus or other connection, without limitation. In one or more examples, logic at the SBC 202 (e.g., CSR 212, Vsup monitor & logic 210, or both) determines and generates the control signals. In one or more examples, both options are available.

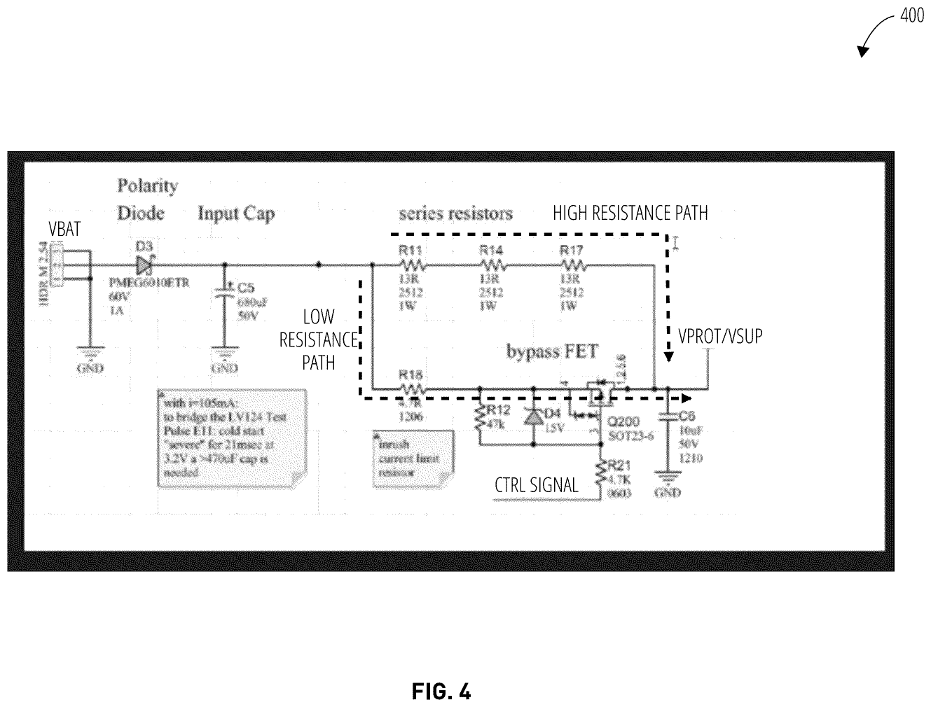

FIG. 4 is an example of a selective voltage protection circuit 400 that includes an input for receiving control signals from the SBC. Selective voltage protection circuit 400 is a non-limiting example of a voltage protection circuit 204 of FIG. 2 and FIG. 3.

In the example depicted by FIG. 4, the voltage protection mechanism of selective voltage protection circuit 400 is selectively enabled or disabled in response to the control signal CTRL SIGNAL. When the voltage protection mechanism is disabled, selective voltage protection circuit 400 provides a low resistance path for the battery voltage 214 to the voltage supply input of the SBC 202, which may generally provide the battery voltage 214 or a modestly modified version thereof as supply voltage 218. When the voltage protection mechanism is enabled, selective voltage protection circuit 400 provides a high resistance path for the battery voltage 214 to the voltage supply input of the SBC 202, which attenuates (e.g., attenuates the power level, without limitation) the battery voltage 214 to produce supply voltage 218. Use of other protection mechanisms, such a voltage clamping circuit, a voltage shunting circuit, a voltage kill switch to turn off the path for battery voltage, without limitation, does not exceed the scope of this disclosure.

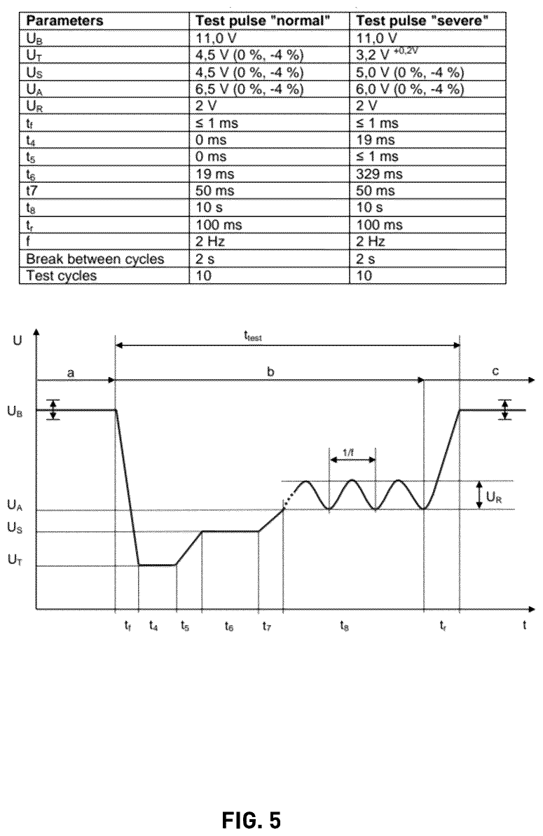

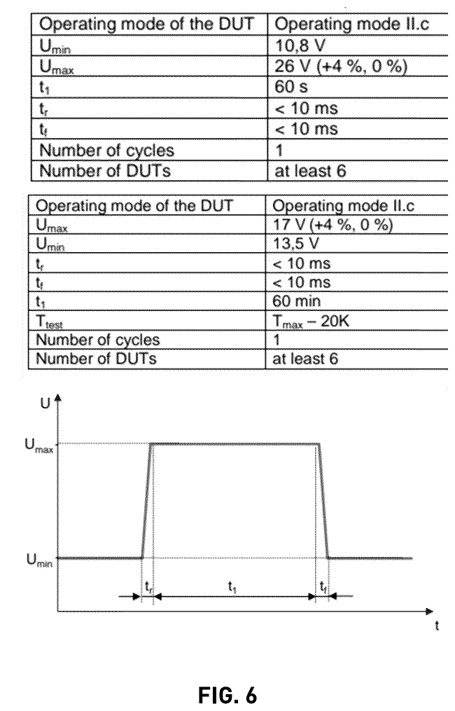

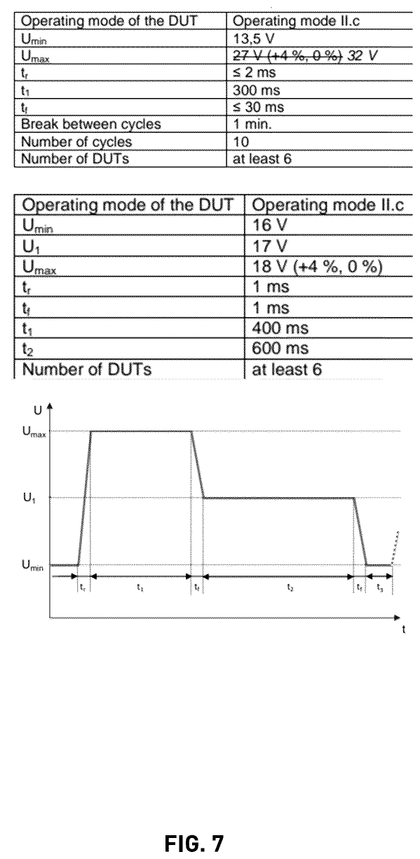

FIG. 5, FIG. 6, and FIG. 7 are examples of conditions that may result in battery stresses. Turning to FIG. 5, it depicts a table at the top and a graph at the bottom.

The table compares parameters under “normal” and “severe” test pulses. These parameters are related to supply voltage conditions that may be detected as discussed above. The parameters include various voltage levels and timings, along with test cycle details. Here is the table:

| Parameters | Test Pulse “Normal” | | Test Pulse “Severe” | |
|---|---|---|---|---|
| U_{B} | 11.0 | V | 11.0 | V |
| U_{T} | 4.5 V (0%, −4%) | | 3.2 V (+0.2 V) | |
| U_{S} | 4.5 V (0%, −4%) | | 5.0 V (0%, −4%) | |
| U_{A} | 6.5 V (0%, −4%) | | 6.0 V (0%, −4%) | |
| U_{R} | 2 | V | 2 | V |
| t_{f} | ≤1 | ms | ≤1 | ms |
| t₄ | 0 | ms | 19 | ms |
| t₅ | 0 | ms | ≤1 | ms |
| t₆ | 19 | ms | 329 | ms |
| t₇ | 50 | ms | 50 | ms |
| t₈ | 10 | s | 10 | s |
| tᵣ | 200 | ms | 200 | ms |
| F | 2 | Hz | 2 | Hz |
| Break between cycles | 2 | s | 2 | s |

| | | |
|---|---|---|
| Test cycles | 10 | 10 |

Below are descriptions of the parameters:
U_{B}: Initial and final battery voltage, constant at 11.0 V for both tests.
U_{T}: Threshold voltage, 4.5 V for “normal” and 3.2 V for “severe.”
U_{S}: Supply voltage, 4.5 V for “normal” and 5.0 V for “severe.”
U_{A}: Alarm voltage, 6.5 V for “normal” and 6.0 V for “severe.”
U_{R}: Reset voltage, 2 V for both tests.
t_{f}: Fall time, ≤1 millisecond for both tests.
t₄: Time interval, 0 millisecond for “normal” and 19 milliseconds for “severe.”
t₅: Time interval, 0 millisecond for “normal” and ≤1 millisecond for “severe.”
t₆: Time interval, 19 milliseconds for “normal” and 329 milliseconds for “severe.”
t₇: Time interval, 50 milliseconds for both tests.
t₈: Time interval, 10 s for both tests.
tᵣ: Recovery time, 100 milliseconds for both tests.
f: Frequency, 2 Hz for both tests.
Break between cycles: 2 seconds for both tests.
Test cycles: 10 for both tests.

The graph shows the variation of voltage (U) over time (t) for a test pulse. Key points and intervals are marked on the graph:
U_{B}: The initial and final battery voltage.
U_{T}: The threshold voltage level.
U_{S}: The supply voltage level.
U_{A}: The alarm voltage level.
U_{R}: The reset voltage level.
t_{f}: Fall time, the duration of time for the voltage to decrease from voltage level U_{B} to U_{T}
t_{f}: Rise time, marking how quickly the voltage increases from voltage level U_{A} to U_{B}.
t₄, t₅, t₆, t₇, t₈: Specific time intervals corresponding to various stages of the test pulse.
f: Frequency of oscillations during a part of the test.
a, b, c: Different phases of the test pulse.

The table and graph together illustrate how the voltage parameters behave under “normal” and “severe” test pulses. The voltage parameters under the severe test pulse have different voltage levels and timings, indicating conditions that could potentially stress the system. The graph visually represents the changes in voltage over time, showing the different phases and how the voltage fluctuates, especially during the “severe” test pulse.

By way of a non-limiting example of a detectable stress on the system: a voltage spike, which is a sudden increase in voltage beyond a normal operating range, may be detected based on the supply voltage U_{S} and alarm voltage U_{A}. the supply voltage U_{S} and alarm voltage U_{A} may indicate spikes if they exceed predefined thresholds (here, 4.5 volts and 6.5 volts, respectively for normal, and 5.0 volts and 6.0 volts for severe).

By way of a further non-limiting example of a detectable stress on the system: a brownout, which is an n voltage below the normal operating range, but not necessarily complete power loss. A brownout condition may be detected based on the supply voltage falling below the threshold voltage U_{T} and staying above the reset voltage U_{R}.

By way of a further non-limiting example of a detectable stress on the system: a Power-On-Reset. A POR is a condition where the supply voltage dips below a reset threshold that could cause the system to reset. A POR condition may be detected based on the supply voltage dipping below a reset threshold U_{R}.

By way of a further non-limiting example of a detectable stress on the system: unsuitable voltage fluctuations. These are variations in voltage over a period, which can cause instability. Patterns of unsuitable voltage fluctuations may be determined based on the parameters related to predetermined time intervals and frequency (e.g., t_{f}, t₄, t₅, t₆, t₇, t₈, tᵣ, and f).

By way of a further non-limiting example of a detectable stress on the system: prolonged low or high voltages. Extended periods where the voltage remains lower or higher than the desired operating range. Patterns of prolonged low or high voltages may be determined based on parameters related to predetermined intervals, such as times t₆ and t₈, which indicating prolonged low or high voltage if the duration of these time intervals are extended beyond predetermined thresholds (e.g., thresholds associated with “normal” time durations, without limitation).

Turning to FIG. 6, it depicts two tables at the top and a graph at the bottom. Each table describes the operating mode of the Device Under Test (DUT) under different conditions.

TABLE 1

| Parameter | Operating Mode of the DUT | |
|---|---|---|
| U_min | 10.8 | V |
| U_max | 26 V (+4%, 0%) | |
| t1 | 60 | s |
| t_r | <10 | ms |
| t_f | <10 | ms |

| | |
|---|---|
| Number of cycles | 1 |
| Number of DUTs | at least 6 |

In Table 1, U_min and U_max represent the minimum and maximum voltage levels, respectively, for the Device Under Test (DUT). Time interval t1 is the time duration for which the DUT is exposed to the maximum voltage (U_max). Time intervals t_r and t_f are the time durations of the rise and fall times, indicating how quickly the voltage transitions between U_min and U_max. The test involves 1 cycle and at least 6 DUTs in this specific non-limiting example.

TABLE 2

| Parameter | Operating Mode of the DUT | |
|---|---|---|
| U_max | 17 V (+4%, 0%) | |
| U_min | 13.5 | V |
| t_r | <10 | ms |
| t_f | <10 | ms |
| t1 | 60 | min |

| | |
|---|---|
| T_test | T_max - 20K |
| Number of cycles | 1 |
| Number of DUTs | at least 6 |

In Table 2, U_max and U_min represent the maximum and minimum voltage levels, respectively, for the DUT. Time interval t1 is the duration for which the DUT is exposed to the maximum voltage (U_max). Time interval t_r and t_f are the rise and fall times, indicating how quickly the voltage transitions between U_min and U_max. Time interval t_test specifies the temperature condition for the test (T_max−20K). The test involves 1 cycle and at least 6 DUTs in this specific non-limiting example.

Both of the test conditions set forth in Table 1 and Table 2 test the DUT under different voltage and time conditions, with Table 1 focusing on short-term high voltage exposure and Table 2 focusing on long-term high voltage exposure under specific thermal conditions. The rise and fall times are kept consistent in both tables to ensure quick voltage transitions.

The graph illustrates the voltage (U) over time (t) for a test pulse. Key points and intervals are marked on the graph:
U_max: The maximum voltage level.
U_min: The minimum voltage level.
t_r: Rise time, the duration for the voltage to rise from U_min to U_max.
t1: The duration for which the voltage remains at U_max.
t_f: Fall time, the duration for the voltage to drop from U_max to U_min.

Turning to FIG. 7, it depicts Table 1 and Table 2 at the top and a graph at the bottom. Each table describes the operating mode of the Device Under Test (DUT) under different conditions.

TABLE 1

| Parameter | Operating Mode of the DUT | |
|---|---|---|
| U_min | 13.5 | V |
| U_max | 27 V (+4%, 0%) 32 V | |
| t_r | ≤2 | ms |
| t1 | 400 | ms |
| t_f | ≤30 | ms |
| Break between cycles | 1 | min. |

| | |
|---|---|
| Number of cycles | 10 |
| Number of DUTs | at least 6 |

In Table 1 of FIG. 7, U_min and U_max represent the minimum and maximum voltage levels, respectively, for the Device Under Test (DUT). Time intervals t_r and t_f are the rise and fall times, indicating how quickly the voltage transitions between U_min and U_max. Time interval t1 is the duration for which the DUT is exposed to the maximum voltage (U_max). Break between cycles specifies a 1-minute interval between test cycles. The test involves 10 cycles and at least 6 DUTs in this specific non-limiting example.

TABLE 2

| Parameter | Operating Mode of the DUT | |
|---|---|---|
| U_min | 16 | V |
| U1 | 17 | V |
| U_max | 18 V (+4%, 0%) | |
| t_r | 1 | ms |
| t_f | 1 | ms |
| t1 | 400 | ms |
| t2 | 600 | ms |

| | |
|---|---|
| Number of DUTs | at least 6 |

In Table 2 of FIG. 7, U_min, U1, and U_max represent the minimum, intermediate, and maximum voltage levels, respectively, for the DUT. Time intervals t_r and t_f are the rise and fall times, indicating how quickly the voltage transitions between levels. Time interval t1 is the duration for which the DUT is exposed to the maximum voltage (U_max). Time interval t2 is the duration for which the DUT is exposed to the intermediate voltage (U1). The test involves at least 6 DUTs, in the specific non-limiting example.

The graph illustrates a voltage cycle for the voltage (U) over time (t) for a test pulse. Key points and intervals are marked on the graph:
U_max: The maximum voltage level.
U1: Intermediate voltage level.
U_min: The minimum voltage level.
t_r: Rise time, the duration for the voltage to rise from U_min to U_max.
t1: The duration for which the voltage remains at U_max.
t_f: Fall time, the duration for the voltage to drop from U_max to U_min.
t2: Duration at intermediate voltage level U1.

In the voltage cycle represented by the graph:
The voltage starts at U_min.
Rises to U_max within the rise time (t_r).
Stays at U_max for a duration (t1).
Falls to an intermediate voltage level U1 and remains there for a duration (t2).
Falls back to U_min within the fall time (t_f).

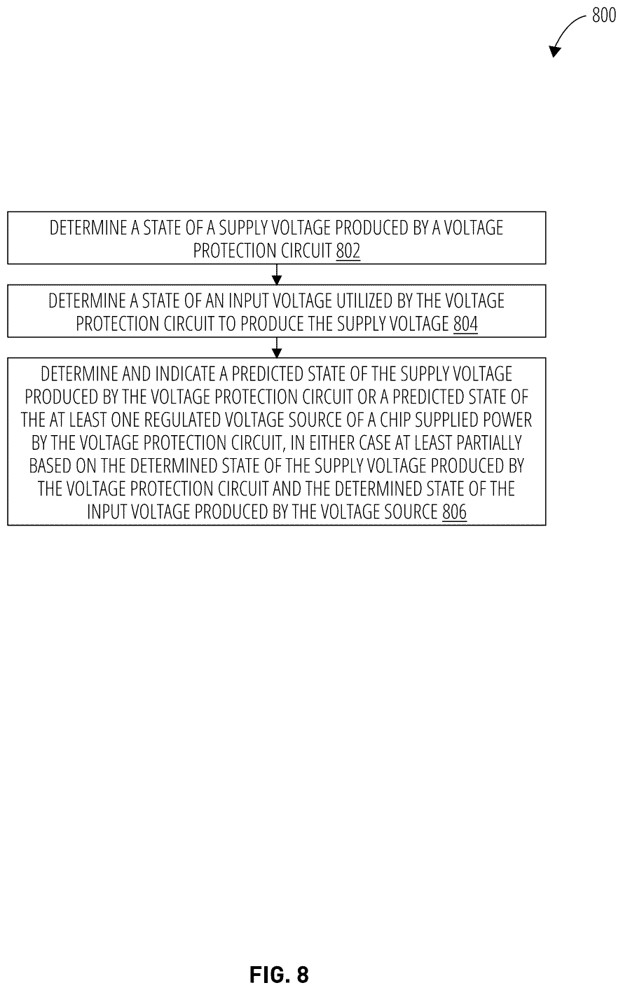

FIG. 8 illustrates an example process 800 for determining a predicted state of a supply voltage that powers a chip or a regulated voltage source of the chip, in accordance with one or more examples. Although the example process 800 depicts a particular sequence of operations, the sequence may be altered without departing from the scope of the present disclosure. For example, some of the operations depicted may be performed in parallel or in a different sequence that does not materially affect the function of the process 800. In other examples, different components of an example device or system that implements the process 800 may perform functions at substantially the same time or in a specific sequence. In one or more examples, some or a totality of operations of process 800 may be performed by system 100 or system 200.

According to some examples, the process may include determining a state of a supply voltage produced by a voltage protection circuit at operation 802.

According to some examples, the process may include determining a state of an input voltage utilized by the voltage protection circuit to produce the supply voltage at operation 804.

According to some examples, the process may include determining and indicate a predicted state of the supply voltage produced by the voltage protection circuit or a predicted state of the at least one regulated voltage source of a chip supplied power by the voltage protection circuit, in either case at least partially based on the determined state of the supply voltage produced by the voltage protection circuit and the determined state of the input voltage produced by the voltage source at operation 806.

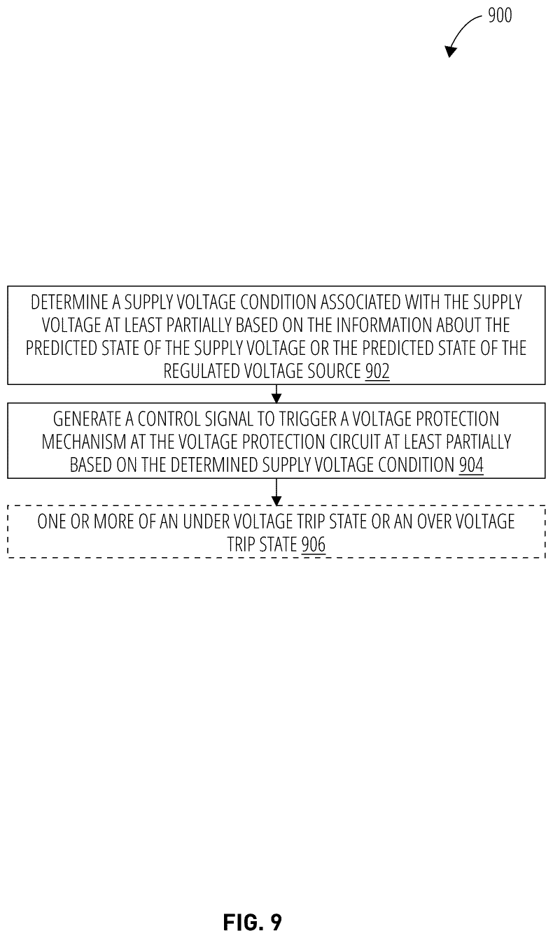

FIG. 9 illustrates an example process 900 for generating a control signal to trigger a voltage protection mechanism based on a predicted state of a supply voltage powering a chip or a regulated voltage source of the chip, in accordance with one or more examples. Although the example process 900 depicts a particular sequence of operations, the sequence may be altered without departing from the scope of the present disclosure. For example, some of the operations depicted may be performed in parallel or in a different sequence that does not materially affect the function of the process 900. In other examples, different components of an example device or system that implements the process 900 may perform functions at substantially the same time or in a specific sequence. In one or more examples, some or a totality of operations of process 900 may be performed by system 100 or system 200.

According to some examples, the process may include determining a supply voltage condition associated with the supply voltage at least partially based on the information about the predicted state of the supply voltage or the predicted state of the regulated voltage source at operation 902.

According to some examples, the process may include generating a control signal to trigger a voltage protection mechanism at the voltage protection circuit at least partially based on the determined supply voltage condition at operation 904.

According to some examples, the process may include one or more of an under voltage trip state or an over voltage trip state at operation 906.

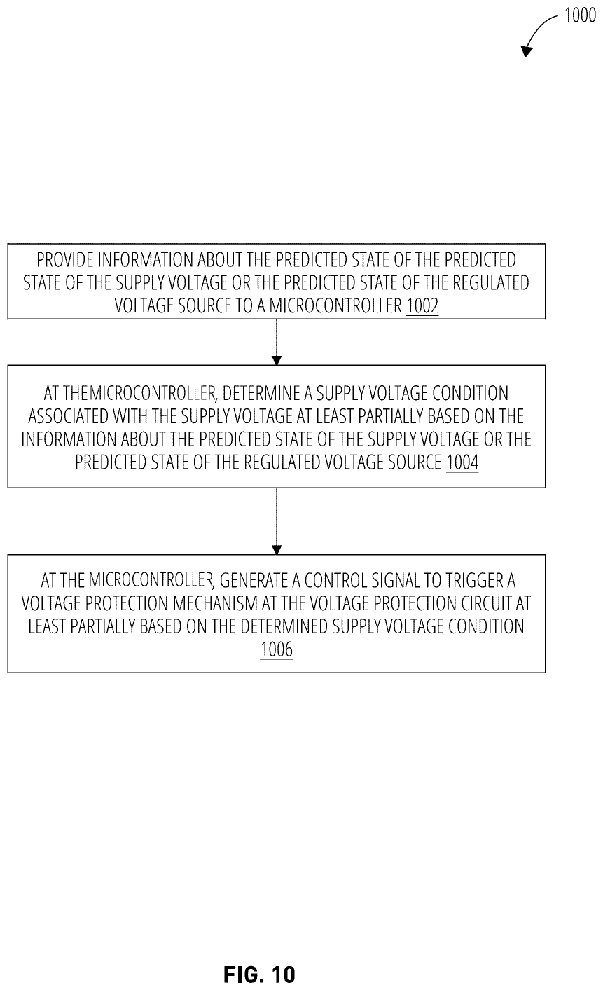

FIG. 10 illustrates an example process 1000 for determining a supply voltage condition, in accordance with one or more examples. Although the example process 1000 depicts a particular sequence of operations, the sequence may be altered without departing from the scope of the present disclosure. For example, some of the operations depicted may be performed in parallel or in a different sequence that does not materially affect the function of the process 1000. In other examples, different components of an example device or system that implements the process 1000 may perform functions at substantially the same time or in a specific sequence.

According to some examples, the process may include providing information about the predicted state of the predicted state of the supply voltage or the predicted state of the regulated voltage source to a microcontroller at operation 1002.

According to some examples, the process may include determining a supply voltage condition associated with the supply voltage at least partially based on the information about the predicted state of the supply voltage or the predicted state of the regulated voltage source at operation 1004.

According to some examples, the process may include generating a control signal to trigger a voltage protection mechanism at the voltage protection circuit at least partially based on the determined supply voltage condition at operation 1006.

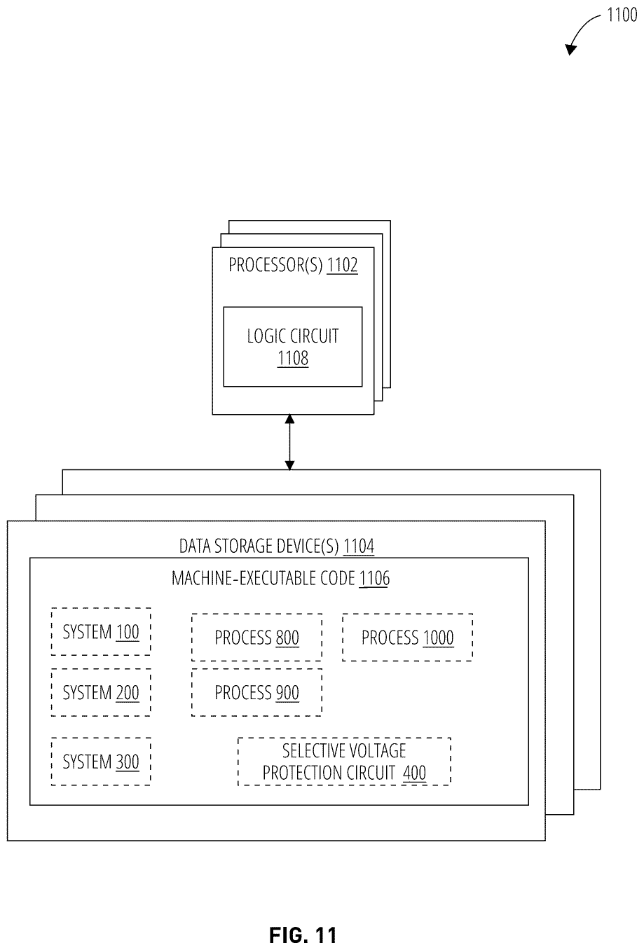

It will be appreciated by those of ordinary skill in the art that functional elements of examples disclosed herein (e.g., functions, operations, acts, processes, or methods) may be implemented in any suitable hardware, software, firmware, or combinations thereof. FIG. 11 illustrates non-limiting examples of implementations of functional elements disclosed herein. In some examples, some or all portions of the functional elements disclosed herein may be performed by hardware capable of carrying out the functional elements.

FIG. 11 is a block diagram of a circuitry 1100 that, in some examples, may be used to implement various functions, operations, acts, processes, or methods disclosed herein. The circuitry 1100 includes one or more processors 1102 (sometimes referred to herein as “processors 1102”) operably coupled to one or more data storage devices 1104 (sometimes referred to herein as “storage 1104”). The storage 1104 includes machine-executable code 1106 stored thereon and the processors 1102 include logic circuit 1108. The machine-executable code 1106 information describing functional elements that may be implemented by (e.g., performed by) the logic circuit 1108. The logic circuit 1108 is adapted to implement (e.g., perform) the functional elements described by the machine-executable code 1106. The circuitry 1100, when executing the functional elements described by the machine-executable code 1106, should be considered as special purpose hardware for carrying out functional elements disclosed herein. In some examples, the processors 1102 may perform the functional elements described by the machine-executable code 1106 sequentially, concurrently (e.g., on one or more different hardware platforms), or in one or more parallel process streams.

When implemented by logic circuit 1108 of the processors 1102, the machine-executable code 1106 adapts the processors 1102 to perform operations of examples disclosed herein. By way of non-limiting example, the machine-executable code 1106 may adapt the processors 1102 to perform some or a totality of features, functions or operations discussed herein.

Also, by way of non-limiting example, the machine-executable code 1106 may adapt the processors 1102 to perform some or a totality of features, functions, or operations disclosed herein for one or more of: the SBC and logic circuits therein for monitoring and adapting to battery voltage stresses. For example, system 100, system 200, or system 300, including voltage source 102, a voltage protection circuit 104, a chip 106, a regulated voltage source 108, and a logic circuit 110.

Also, by way of non-limiting example, the machine-executable code 1106 may adapt the processors 1102 to perform some or a totality of features, functions, or operations disclosed herein for one or more of: process 800, process 900, or process 1000.

The processors 1102 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer executes functional elements corresponding to the machine-executable code 1106 (e.g., software code, firmware code, hardware descriptions) related to examples of the present disclosure. It is noted that a general-purpose processor (may also be referred to herein as a host processor or simply a host) may be a microprocessor, but in the alternative, the processors 1102 may include any conventional processor, controller, microcontroller, or state machine. The processors 1102 may also be implemented as a combination of computing devices, such as a combination of a DSP and a microprocessor, a plurality of microprocessors, one or more microprocessors in conjunction with a DSP core, or any other such configuration.

In some examples, the storage 1104 includes volatile data storage (e.g., random-access memory (RAM)), non-volatile data storage (e.g., Flash memory, a hard disc drive, a solid-state drive, erasable programmable read-only memory (EPROM), without limitation). In some examples, the processors 1102 and the storage 1104 may be implemented into a single device (e.g., a semiconductor device product, a system on chip (SOC), without limitation). In some examples, the processors 1102 and the storage 1104 may be implemented into separate devices.

In some examples, the machine-executable code 1106 may include computer-readable instructions (e.g., software code, firmware code). By way of non-limiting example, the computer-readable instructions may be stored by the storage 1104, accessed directly by the processors 1102, and executed by the processors 1102 using at least the logic circuit 1108. Also, by way of non-limiting example, the computer-readable instructions may be stored on the storage 1104, transferred to a memory device (not shown) for execution, and executed by the processors 1102 using at least the logic circuit 1108. Accordingly, in some examples, the logic circuit 508 includes electrically configurable logic circuit 1108.

In some examples, the machine-executable code 1106 may describe hardware (e.g., circuitry) to be implemented in the logic circuit 1108 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, SystemVerilog or very large-scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 1108 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples, the machine-executable code 1106 may include an HDL, an RTL, a GL description, a mask level description, other hardware description, or any combination thereof.

In examples where the machine-executable code 1106 includes a hardware description (at any level of abstraction), a system (not shown, but including the storage 1104) implements the hardware description described by the machine-executable code 1106. By way of non-limiting example, the processors 1102 may include a programmable logic device (e.g., an FPGA or a PLC) and the logic circuit 1108 may be electrically controlled to implement circuitry corresponding to the hardware description into the logic circuit 1108. Also, by way of non-limiting example, the logic circuit 1108 may include hard-wired logic manufactured by a manufacturing system (not shown, but including the storage 1104) according to the hardware description of the machine-executable code 1106.

Regardless of whether the machine-executable code 1106 includes computer-readable instructions or a hardware description, the logic circuit 1108 is adapted to perform the functional elements described by the machine-executable code 1106 when implementing the functional elements of the machine-executable code 1106. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: a voltage source; a voltage protection circuit; and a system-basis-chip powered at least in part via the voltage protection circuit, wherein the system-basis-chip includes: at least one regulated voltage source; and a logic circuit to: determine a state of a supply voltage produced by the voltage protection circuit; determine a state of an input voltage produced by the voltage source; and determine and indicate a predicted state of the supply voltage produced by the voltage protection circuit or a predicted state of the at least one regulated voltage source, in either case at least partially based on the determined state of the supply voltage produced by the voltage protection circuit and the determined state of the input voltage produced by the voltage source.

Example 2: The apparatus according to Example 1, wherein the logic circuit includes predetermined associations between predicted states and stresses on a system.

Example 3: The apparatus according to any of Examples 1 and 2, wherein the voltage source is a battery.

Example 4: The apparatus according to any of Examples 1 through 3, wherein the voltage protection circuit to produce the supply voltage at least partially responsive to a control signal.

Example 5: The apparatus according to any of Examples 1 through 4, wherein the voltage protection circuit includes a voltage protection mechanism, and wherein the logic circuit to generate the control signal to trigger the voltage protection mechanism at least partially responsive to detection of a supply voltage condition.

Example 6: The apparatus according to any of Examples 1 through 5, wherein the supply voltage condition detectable by the logic circuit includes one or more of an under voltage trip state or an over voltage trip state.

Example 7: The apparatus according to any of Examples 1 through 6, wherein the logic circuit comprises: a memory to store the predicted state of the supply voltage or the state of the at least one regulated voltage source; and an output to read the predicted state from the memory.

Example 8: The apparatus according to any of Examples 1 through 7, wherein the logic circuit comprises: a further output to indicate when the memory is ready to be read.

Example 9: The apparatus according to any of Examples 1 through 8, comprising: a voltage divider having an input coupled to an output of the voltage source, wherein the logic circuit to determine a predicted state of the supply voltage produced by the voltage protection circuit or a predicted state of the regulated voltage source at least partially based on an output of the voltage divider.

Example 10: The apparatus according to any of Examples 1 through 9, comprising: a microcontroller to: receive information about the predicted state of the supply voltage or the predicted state of the predicted state of the regulated voltage source; determine a supply voltage condition at least partially based on the information about the predicted state of the supply voltage or the predicted state of the regulated voltage source; and generate a control signal to trigger a voltage protection mechanism at the voltage protection circuit at least partially based on the determined supply voltage condition.

Example 11: The apparatus according to any of Examples 1 through 10, wherein the microcontroller provides the control signal directly to the voltage protection circuit.

Example 12: The apparatus according to any of Examples 1 through 11, wherein the microcontroller provides the control signal to the voltage protection circuit indirectly via the logic circuit.

Example 13: A method, comprising: determining a state of a supply voltage produced by a voltage protection circuit; determining a state of an input voltage utilized by the voltage protection circuit to produce the supply voltage; and determining and indicating a predicted state of the supply voltage produced by the voltage protection circuit or a predicted state of at least one regulated voltage source of a chip supplied power by the voltage protection circuit, in either case at least partially based on the determined state of the supply voltage produced by the voltage protection circuit and the determined state of the input voltage produced by the voltage source.

Example 14: The method according to Example 13, comprising: determining a supply voltage condition associated with the supply voltage at least partially based on information about the predicted state of the supply voltage or the predicted state of the regulated voltage source; and generating a control signal to trigger a voltage protection mechanism at the voltage protection circuit at least partially based on the determined supply voltage condition.

Example 15: The method according to any of Examples 13 and 14, wherein the supply voltage condition detectable by a logic circuit includes one or more of an under voltage trip state or an over voltage trip state.

Example 16: The method according to any of Examples 13 through 15, comprising: providing information about the predicted state of the predicted state of the supply voltage or the predicted state of the regulated voltage source to a microcontroller; and at the microcontroller: determining a supply voltage condition associated with the supply voltage at least partially based on the information about the predicted state of the supply voltage or the predicted state of the regulated voltage source; and generating a control signal to trigger a voltage protection mechanism at the voltage protection circuit at least partially based on the determined supply voltage condition.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

1. An apparatus, comprising:
a voltage source;
a voltage protection circuit; and
a system-basis-chip powered at least in part via the voltage protection circuit, wherein the system-basis-chip includes:
at least one regulated voltage source; and
a logic circuit to:
determine a state of a supply voltage produced by the voltage protection circuit;
determine a state of an input voltage produced by the voltage source; and
determine and indicate a predicted state of the supply voltage produced by the voltage protection circuit or a predicted state of the at least one regulated voltage source, in either case at least partially based on the determined state of the supply voltage produced by the voltage protection circuit and the determined state of the input voltage produced by the voltage source.

2. The apparatus of claim 1, wherein the logic circuit includes predetermined associations between predicted states and stresses on a system.

3. The apparatus of claim 1, wherein the voltage source is a battery.

4. The apparatus of claim 1, wherein the voltage protection circuit to produce the supply voltage at least partially responsive to a control signal.

5. The apparatus of claim 4, wherein the voltage protection circuit includes a voltage protection mechanism, and wherein the logic circuit to generate the control signal to trigger the voltage protection mechanism at least partially responsive to detection of a supply voltage condition.

6. The apparatus of claim 5, wherein the supply voltage condition detectable by the logic circuit includes one or more of an under voltage trip state or an over voltage trip state.

7. The apparatus of claim 5, wherein the logic circuit comprises:
a memory to store the predicted state of the supply voltage or the state of the at least one regulated voltage source; and
an output to read the predicted state from the memory.

8. The apparatus of claim 7, wherein the logic circuit comprises:
a further output to indicate when the memory is ready to be read.

9. The apparatus of claim 1, comprising:
a voltage divider having an input coupled to an output of the voltage source,
wherein the logic circuit to determine a predicted state of the supply voltage produced by the voltage protection circuit or a predicted state of the regulated voltage source at least partially based on an output of the voltage divider.

10. The apparatus of claim 1, comprising:
a microcontroller to:
receive information about the predicted state of the supply voltage or the predicted state of the predicted state of the regulated voltage source;
determine a supply voltage condition at least partially based on the information about the predicted state of the supply voltage or the predicted state of the regulated voltage source; and
generate a control signal to trigger a voltage protection mechanism at the voltage protection circuit at least partially responsive to the determined supply voltage condition.

11. The apparatus of claim 10, wherein the microcontroller to transition to a low power state that reduces load on the supply voltage at least partially responsive to the determined supply voltage condition.

12. The apparatus of claim 10, wherein the microcontroller provides the control signal directly to the voltage protection circuit.

13. The apparatus of claim 10, wherein the microcontroller provides the control signal to the voltage protection circuit indirectly via the logic circuit.

14. A method, comprising:
determining a state of a supply voltage produced by a voltage protection circuit;
determining a state of an input voltage utilized by the voltage protection circuit to produce the supply voltage; and
determining and indicating a predicted state of the supply voltage produced by the voltage protection circuit or a predicted state of at least one regulated voltage source of a chip supplied power by the voltage protection circuit, in either case at least partially based on the determined state of the supply voltage produced by the voltage protection circuit and the determined state of the input voltage produced by the voltage source.

15. The method of claim 14, comprising:
determining a supply voltage condition associated with the supply voltage at least partially based on information about the predicted state of the supply voltage or the predicted state of the regulated voltage source; and
generating a control signal to trigger a voltage protection mechanism at the voltage protection circuit at least partially based on the determined supply voltage condition.

16. The method of claim 15, wherein the supply voltage condition detectable by a logic circuit includes one or more of an under voltage trip state or an over voltage trip state.

17. The method of claim 14, comprising:
providing information about the predicted state of the predicted state of the supply voltage or the predicted state of the regulated voltage source to a microcontroller; and
at the microcontroller:
determining a supply voltage condition associated with the supply voltage at least partially based on the information about the predicted state of the supply voltage or the predicted state of the regulated voltage source; and
generating a control signal to trigger a voltage protection mechanism at the voltage protection circuit at least partially based on the determined supply voltage condition.
